(19) United States
(12) Patent Application Publication
(10) Pub. No.: US 2026/0255668 A1
(43) Pub. Date: Aug. 27, 2026

(54) LOW LEAKAGE CMOS INVERTER

(71) Applicant: GlobalFoundries U.S. Inc., Malta, NY (US)

(72) Inventors: Jeffrey Bowman Johnson, North Hero, VT (US); Maria Toledano Luque, Mechanicville, NY (US); Wei Ma, Clifton Park, NY (US); Sangameshwar Rao Saudari, Rexford, NY (US)

(21) Appl. No.: 19/059,724

(22) Filed: Feb. 21, 2025

(51) Int. Cl. H10D 84/85

(52) U.S. Cl. CPC H10D 84/853

(57) ABSTRACT

The present disclosure relates to semiconductor structures and, more particularly, to a low leakage digital logic inverter circuit and methods of manufacture. The structure includes an inverter with a first transistor and a second transistor, the first transistor comprising a gate dielectric material and a gate electrode, the second transistor comprising a gate dielectric material and a gate electrode. A thickness of the gate dielectric material of the second transistor is greater than a thickness of the gate dielectric material of the first transistor.

### BACKGROUND

The present disclosure relates to semiconductor structures and, more particularly, to a low leakage digital logic inverter circuit and methods of manufacture.

An inverter circuit is the fundamental building block of digital logic circuit. The role of the inverter circuit is to reverse the applied input signal, from high to low or from low to high. In particular, the implementation of inverters in CMOS (complementary metal oxide semiconductor) microelectronics technologies has made such technologies the drivers of VLSI (very large scale integrated) circuits because once the switching process has been accomplished, very little current flows in the circuit. This low-power characteristic of CMOS inverters has enabled increasingly higher levels of integration and/or ultra-low power circuits.

### SUMMARY

In an aspect of the disclosure, a structure comprises an inverter with a first transistor and a second transistor, the first transistor comprising a gate dielectric material and a gate electrode, the second transistor comprising a gate dielectric material and a gate electrode. A thickness of the gate dielectric material of the second transistor is greater than a thickness of the gate dielectric material of the first transistor.

In an aspect of the disclosure, a structure comprising: a first transistor comprising at least one gate dielectric layer with a first thickness; a second transistor comprise at least one gate dielectric with a second thickness greater than the first thickness; a source of the first transistor connected to Vdd and a drain of the first transistor connected to an output terminal; and a source of the second transistor connected to ground and a drain of the second transistor connected to the output terminal.

In an aspect of the disclosure, a method comprises: forming a first transistor comprising a gate dielectric material and a gate electrode; and forming a second transistor comprising a gate dielectric material and a gate electrode. A thickness of the gate dielectric material of the second transistor is greater than a thickness of the gate dielectric material of the first transistor.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows an electrical schematic diagram of an inverter in accordance with aspects of the present disclosure.

FIG. 2 shows a structure and respective fabrication processes in accordance with aspects of the present disclosure.

### DETAILED DESCRIPTION

The present disclosure relates to semiconductor structures and, more particularly, to a low leakage digital logic inverter circuit and methods of manufacture. More specifically, the low leakage inverter is a super low leakage CMOS inverter. In embodiments, the low leakage inverter includes two transistors with different physical gate dielectric layer(s) (e.g., oxide). For example, a gate dielectric layer of a first transistor may be thicker than the gate dielectric layer of a second transistor. Advantageously, the present disclosure enables very low leakage logic technology without the need for layout changes. The inverter described herein also reduces the effective capacitance (Ceff) of the device resulting in higher ring oscillator (RO) frequency.

In more specific embodiments, the inverter comprises a first FET transistor with a source connected to a power supply, a drain connected to an output terminal and a gate electrode. A second FET transistor comprises a source connected to ground, a drain connected to the output terminal, and a gate electrode. An input terminal may be connected to the gate electrodes of the first and second transistors. The first and second transistors may contain one or multiple gate dielectric layers in which at least one gate dielectric layer is different, e.g., thicker, for one transistor than the other transistor. That is, the gate dielectric layer(s) of the different transistors are not identical.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

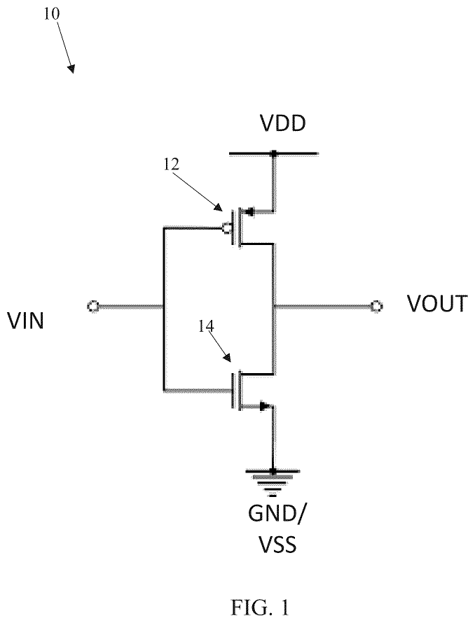

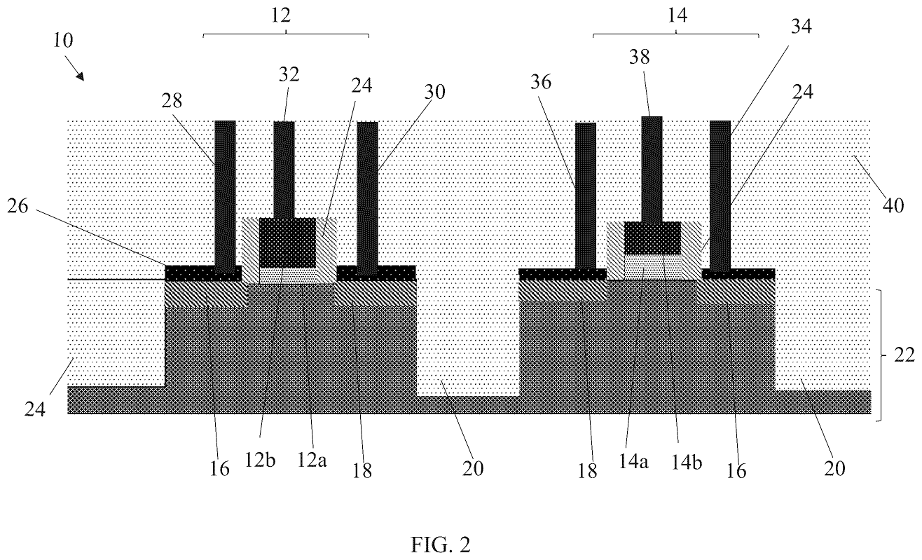

FIG. 1 shows an electrical schematic diagram of an inverter in accordance with aspects of the present disclosure. In embodiments, the inverter 10 includes a first transistor 12 and a second transistor 14. The first transistor 12 may be a PFET and the second transistor 14 may be an NFET; although it is contemplated that the first transistor 12 may be an NFET and the second transistor 14 may be an PFET. Hereinafter, the disclosure is discussed with respect to the first transistor 12 being a PFET and the second transistor 14 may be an NFET. Furthermore, in embodiments, the first transistor 12 and the second transistor 14 may be respective finFETs. The transistors 12, 14 each include one or more gate dielectric materials and a gate electrode. In embodiments, the one or more gate dielectric materials may be of different thicknesses for the different transistors 12, 14. For example, in one implementation, the one or more gate dielectric materials of the second transistor 14 may be thicker than the one or more gate dielectric materials of the first transistor 12; although other variations are also contemplated as described herein with respect to FIG. 2.

Still referring to FIG. 1, in embodiments, the first transistor 12 includes a source region connected to a power supply VDD and a drain region connected to an output terminal Vout. The second transistor comprises 14 comprises a source region connected to ground GND/VSS and a drain region connected to an output terminal VOUT. An input terminal Vin may be connected to the gate electrodes of both the first transistor 12 and the second transistor 14.

FIG. 2 shows a structure and respective fabrication processes in accordance with aspects of the present disclosure. In embodiments, the structure 10 of FIG. 2 includes adjacent gate structures 12, 14 with a respective source/drain region 16, 18. The adjacent gate structures 12, 14 may be isolated from one another by a shallow trench isolation structure 20. The adjacent gate structures 12, 14 may be, for example, field effect transistors (FETs). In more specific embodiments, the gate structure 12 may be a PFET and the gate structure 14 may be a NFET. In embodiments, the FETs may be finFETs. The gate structures 12, 14 include respective gate dielectric materials 12a, 14a and respective gate electrodes 12b, 14b. The gate dielectric materials 12a, 14a may be one or more layers of gate dielectric material. The gate dielectric material 12a, 14a may be different thicknesses as described in more detail below.

More specifically, the structure 10 includes a semiconductor substrate 22. In embodiments, the semiconductor substrate 22 may be a bulk semiconductor substrate or semiconductor-on-insulator technology. In the semiconductor-on-insulator technology, the semiconductor substrate 22 may include a semiconductor handle wafer, a buried insulator layer and a top semiconductor layer. In embodiments, the semiconductor substrate 22 (in either the semiconductor-on-insulator technology or bulk technology) may comprise any suitable semiconductor material such as, for example, Si, Ge, SiGe, SiC, SiGeC, a III-V compound semiconductor, a II-VI compound semiconductor or any combinations thereof. The semiconductor material may comprise any suitable single crystallographic orientation (e.g., a (100), (110), (111), or (001) crystallographic orientation).

Shallow trench isolation structures 20 may be formed in the semiconductor substrate 22. The shallow trench isolation structures 20 can be formed by conventional lithography, etching and deposition methods known to those of skill in the art. For example, a resist formed over the top semiconductor substrate 22 is exposed to energy (light) and developed utilizing a conventional resist developer to form a pattern (opening). An etching process with a selective chemistry, e.g., reactive ion etching (RIE), will be used to transfer the pattern from the photoresist layer to form one or more trenches in the semiconductor substrate 22 through the openings of the resist. Following the resist removal by a conventional oxygen ashing process or other known stripants, insulator material (e.g., silicon dioxide) can be deposited by any conventional deposition processes, e.g., CVD process. Any residual material on the surface of the semiconductor substrate 22 can be removed by conventional chemical mechanical polishing (CMP) processes.

FIG. 2 further shows the adjacent gate structures 12, 14 with respective gate dielectric materials 12a, 14a and respective gate electrodes 14b, 14b. The gate structures 12, 14 also include respective source/drain regions 16, 18. In embodiments, the respective source/drain regions 16, 18 may be formed on opposing sides of the adjacent gate structures 12, 14, with the respective source or drain regions of each of the adjacent gate structures 12, 14 separated (e.g., isolated) from one another by the shallow trench isolation structure 20. The source/drain regions 16, 18 may be raised diffusion regions formed by an in-situ doped epitaxial process or, alternatively, may be planar structures formed by an ion implantation process.

The adjacent gate structures 12, 14 can be fabricated using conventional CMOS processes, with a gate dielectric material (designated at reference numerals 12a, 14a) and a workfunction metal material (designated at reference numerals 12b, 14b) and sidewall spacers 24. For example, in the CMOS processing, a gate dielectric 12a, 14a and workfunction metal material, e.g., gate electrode 12b, 14b are formed, e.g., deposited, onto the semiconductor substrate 22. The gate dielectrics 12a, 14a and the gate electrode 12b, 14b may be blanket deposited using, for example, an atomic layer deposition (ALD) process and the may be blanket deposited using a conventional CVD process. The gate dielectric material and the workfunction metal material may be subjected to a patterning process, e.g., conventional lithography and etching (RIE) processes. In embodiments, the gate electrode 12b, 14b may be workfunction metal including TiN, TaN, TaAlC, TiC, TiAl, TaC, Co, Al, TiAl, HfTi, TiSi, TaSi or TiAlC. In embodiments, the workfunction metal may be replaced with polysilicon material (in which case a silicide contact will be formed over the polysilicon material).

In further embodiments, the gate dielectric material 12a, 14a can be one or multiple layers of gate dielectric material such as a high-k gate dielectric material, e.g., a hafnium based material and a low-k dielectric layer, e.g., oxide material, or combinations thereof. In preferred embodiments, the low-k dielectric material may contact the semiconductor substrate 22, e.g., bulk substrate. In a multi-layered embodiment, the high-k dielectric material would be deposited over the oxide material.

In specific embodiments, the dielectric material 12a may have a different thickness than the dielectric material 14a. For example, the dielectric material 14a may be thicker than the dielectric material 12a. In such embodiments, the gate dielectric material for the gate structures 12, 14 may be formed in different deposition processes, with a blocking material used to prevent the thicker or additional dielectric material from growing or being deposited on the other side of the structure, e.g., for the gate structure with the thinner gate dielectric material.

More specifically, the dielectric material 14a for an NFET device may be thicker than the dielectric material 12a for a PFET device; although other configurations may be contemplated herein. By way of illustrative and non-limiting examples, in practice, the dielectric material 14a may include a thicker oxide layer than the dielectric material 12a, with the high-k dielectric materials for both devices being the same thickness. Alternatively, the high-k dielectric material 14a for the NFET device may be thicker than the high-k dielectric material 12a for the PFET device, with the oxide material being the same thickness for both devices. As still another alternative, the both high-k dielectric material and the oxide material for the NFET device may be thicker than both the high-k dielectric material and the oxide material for the PFET device.

The sidewall spacers 24 may be formed by blanket deposition of an insulator material over the patterned gate dielectric materials 12a, 14a and gate electrodes 12b, 14b, e.g., workfunction metal material. The insulator material may be nitride or oxide or combinations thereof. Following the blanket deposition process, CVD, an anisotropic etching process may be performed to form the sidewall spacers 24.

The source/drain regions 16, 18 may be formed by an in-situ doped epitaxial process. For example, epitaxy regions (source/drain regions) are formed by selectively growing a semiconductor material, e.g., silicon germanium or silicon on sides of the adjacent gate structures 12, 14. It should be understood by those of skill in the art that other semiconductor materials and compounds known in the art are contemplated for use herein. A p-type or an n-type impurity may be used as a dopant during the epitaxial process, depending on whether the resulting FET is a p-type FET or an n-type FET. For example, the in-situ dopant may be boron for a p-type FET and phosphorus for an n-type FET.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth can be performed utilizing any well-known precursor gas or gas mixture. Carrier gases like hydrogen, nitrogen, helium and argon can be used.

Alternatively, the diffusion regions, e.g., source regions 16 and drain regions 18, may be formed by introducing a dopant by, for example, ion implantation that introduces a concentration of a dopant in the semiconductor substrate 22. In embodiments, patterned implantation masks may be used to define selected areas exposed for the implantations. The implantation masks may include a layer of a light-sensitive material, such as an organic photoresist, applied by a spin coating process, pre-baked, exposed to light projected through a photomask, baked after exposure, and developed with a chemical developer. The implantation mask has a thickness and stopping power sufficient to block masked areas against receiving a dose of the implanted ions.

FIG. 2 further shows silicide contacts 26 to the source/drain regions 16, 18. As should be understood by those of skill in the art, the silicide process begins with deposition of a thin transition metal layer, e.g., nickel, cobalt or titanium, over fully formed and patterned semiconductor devices (e.g., doped or ion implanted source and drain regions 16, 18). After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts 26 in the active regions of the device. It should be understood by those of skill in the art that silicide contacts will not be required when a gate structure is composed of a metal material.

Contacts 28, 30, 32, 34, 36, 38 may be formed to the respective source regions 16 and drain regions 18 and the gate electrodes 12b, 14b. In embodiments, the contacts 28, 30, 32, 34, 36, 38 may be formed from any conventional conductive material. For example, the contacts 28, 30, 32, 34, 36, 38 may be tungsten or aluminum, lined with Tan or TiN. The contacts 28, 30, 32, 34, 36, 38 may be formed through an interlevel dielectric material 40, e.g., silicon dioxide, by any conventional lithography, etching and deposition process as known in the art such that a further explanation is not required for a person of ordinary skill to practice the present disclosure.

In embodiments, the contact 32 of the first transistor 12 may be connected to a power supply Vin. Similarly, the contact 38 of the second transistor 14 may be connected to the power supply Vin. Also, in embodiments, the contact 28 of the first transistor 12 may be connected to VDD (or VSS depending on the arrangement of the two transistors 12, 14). Similarly, the contact 34 of the second transistor 14 may be connected VSS (or VDD depending on the arrangement of the two transistors 12, 14). Moreover, in embodiments, the contact 30 of the first transistor 12 may be connected to Vout (or VSS depending on the arrangement of the two transistors 12, 14). Similarly, the contact 36 of the second transistor 14 may be connected to Vout. It should be recognized that the first transistor 12 the second transistor 14 may either be connected to VDD or VSS, respectively, depending on the arrangement of the transistors, 12, 14.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising an inverter with a first transistor and a second transistor, the first transistor comprising a gate dielectric material and a gate electrode, the second transistor comprising a gate dielectric material and a gate electrode, wherein a thickness of the gate dielectric material of the second transistor is greater than a thickness of the gate dielectric material of the first transistor.

2. The structure of claim 1, wherein the first transistor comprises a PFET and the second transistor comprises an NFET.

3. The structure of claim 2, wherein the PFET and the NFET comprise finFETs.

4. The structure of claim 1, wherein the gate dielectric material of the first transistor and the second transistor comprise one of a single gate dielectric material and multiple layers of gate dielectric material.

5. The structure of claim 4, wherein the multiple layers of the gate dielectric material comprise a low-k dielectric material and a high-k dielectric material.

6. The structure of claim 5, wherein the high-k dielectric material is over the low-k dielectric material.

7. The structure of claim 6, wherein the low-k dielectric material of the second transistor is thicker than the low-k dielectric material of the first transistor.

8. The structure of claim 4, wherein the multiple layers of the gate dielectric material of the first transistor and the second transistor comprise two different materials with a lower dielectric material being thicker than an upper dielectric material.

9. The structure of claim 1, wherein the gate electrode of the first transistor and the second transistor comprise a polysilicon material.

10. The structure of claim 1, wherein:
the first transistor comprises a source connected to a power supply, a drain connected to an output terminal and the gate electrode connected to an input terminal; and
the second transistor comprise a source connected to ground, a drain connected to the output terminal, and the gate electrode connected the input terminal.

11. A structure comprising:
a first transistor comprising at least one gate dielectric layer with a first thickness;
a second transistor comprise at least one gate dielectric with a second thickness greater than the first thickness;
a source of the first transistor connected to Vdd and a drain of the first transistor connected to an output terminal; and
a source of the second transistor connected to ground and a drain of the second transistor connected to the output terminal.

12. The structure of claim 11, wherein the first transistor comprises a PFET and the second transistor comprises an NFET.

13. The structure of claim 12, wherein the PFET and the NFET comprise finFETs on a bulk semiconductor substrate.

14. The structure of claim 12, wherein the gate dielectric material of the first transistor and the second transistor comprise multiple layers of gate dielectric material.

15. The structure of claim 14, wherein the multiple layers of the gate dielectric material comprise a low-k dielectric material underneath a high-k dielectric material.

16. The structure of claim 15, wherein the low-k dielectric material of the second transistor is thicker than the low-k dielectric material of the first transistor.

17. The structure of claim 15, wherein the high-k dielectric material of the second transistor is thicker than the high-k dielectric material of the first transistor.

18. The structure of claim 15, wherein the low-k dielectric material and the high-k dielectric material of the second transistor is thicker than the low-k dielectric material and the high-k dielectric material of the first transistor.

19. The structure of claim 14, wherein the first transistor and the second transistor comprise a gate electrode comprising a polysilicon material connecting to Vin.

20. A method comprising:
forming a first transistor comprising a gate dielectric material and a gate electrode; and
forming a second transistor comprising a gate dielectric and a gate electrode,
wherein a thickness of the gate dielectric material of the second transistor is greater than a thickness of the gate dielectric material of the first transistor.
